(19) United States
(12) Patent Application Publication
(10) Pub. No.: US 2004/0145939 A1
(43) Pub. Date: Jul. 29, 2004

(54) Non-volatile semiconductor storage device and production method thereof

(76) Inventors: Keichi Yoshida, Musashimurayama (JP); Atsushi Nozoe, Hino (JP)

Correspondence Address: MILES & STOCKBRIDGE PC, 1751 PINNACLE DRIVE, SUITE 500, MCLEAN, VA, 22102-3833, US

(21) Appl. No.: 10/478,095

(22) PCT Filed: Apr. 12, 2002
(86) PCT No.: PCT/JP02/03649

(30) Foreign Application Priority Data
May 31, 2001 (JP) 2001-165175

(51) Int. Cl. G11C 11/22

(52) U.S. Cl. 365/145

(57) ABSTRACT

In a method for producing non-volatile semiconductor storage devices, a non-volatile semiconductor storage devices comprises a memory array (10) that includes a plurality of non-volatile storage elements and a plurality of spare storage elements, each of which enables information to be written/erased therein/therefrom electrically, and a storage element, if it is decided to be defective during a write operation, is replaced with one of the spare storage elements (10a), and information related to the defective storage element is stored in a predetermined area (10b) provided in the memory array. In the method, if the defective storage element is detected by a test, the information related to each detected defective storage element is not stored in the predetermined area of the memory array, and the one in which a rate of the defective storage elements detected by the test is under a predetermined value is extracted as a non-defective product.

### TECHNICAL FIELD

The present invention relates to a technique to be employed effectively for non-volatile memories, each enabling information to be written/erased therein/therefrom electrically and having a circuit for relieving defective cells, as well as a production method thereof, more particularly to a technique to be employed effectively for flash memories.

### BACKGROUND ART

A flash memory is composed of memory cells that are non-volatile storage elements, each of which is formed with a double-gate structured MOSFET provided with both control gate and floating gate. In the flash memory, each memory cell MOSFET changes the charge accumulated in its floating gate to change the threshold voltage thereof so as to record information therein.

In the flash memory, however, writing/erasing of information in/from the memory cells often causes the threshold voltage to be varied and the writing/erasing characteristics of the memory itself come to be degraded as it is kept used. To avoid such problems, the flash memory is usually provided with a status register in itself so that the write/erasure error bit is set in the status register if a write/erasure operation is ended abnormally, thereby the write/erasure error is reported to external.

Furthermore, there is a conventional flash memory that includes a controller provided with an address translation table ATB as shown in FIG. 9A for translating logical addresses received from a CPU to physical addresses handled in the flash memory. The controller (hereinafter, to be referred to as a flash controller) issues write and erase commands to the flash memory. If a write/erasure error occurs, therefore, the flash controller updates the address translation table so as to exclude the defective sector that includes the error-occurred memory cell from the effective memory area, thereby accesses to the error-occurred sector are avoided. In that connection, in the defective sector management area is also recorded information for denoting that the sector is abnormal.

There is another conventional flash memory provided with a so-called redundancy circuit composed of a plurality of spare memory cells and an address replacement circuit ARC just like such a non-volatile memory as a DRAM, so that the address replacement circuit ARC, when a defective memory cell is detected in a probe test performed for a wafer, executes a relieving processing (hereinafter, to be referred to a redundant relieving processing) in which the defective memory sector is replaced with a redundant one as shown in FIG. 9B. This redundant relieving processing is done separately from the defective sector management by the flash controller described above.

The address replacement circuit ARC used for such redundant relieving processings is usually composed so as to store each defective sector address in a fuse sector beforehand and decide whether or not an address inputted during a normal operation matches with the defective address and if they match, the defective sector is replaced with a predetermined spare one to continue the access. However, such a redundant relieving processing is usually made for each wafer, that is, before each chip is cut apart from the wafer and sealed in a package. It has thus been impossible to relieve defective sectors with use of the redundancy circuit after delivery.

On the other hand, there is a method disclosed in Japanese Unexamined Patent Publication No. 10 (1998)-177799. According to the method, when a defective memory cell is found, the position is recorded in part of the non-volatile memory cell and it is read when the flash memory is powered so as not to access the defective memory cell, thereby both redundant memory rows and replacement circuit are omitted. There is another method disclosed in Japanese Unexamined Patent Publication No. 8 (1996)-7597. According to the method, if a defective memory cell is detected in the flash memory during a normal operation, the cell is replaced with a redundant one immediately. However, the official gazette does not mention to any test method.

FIG. 8 shows a redundant relieving procedure employed for a conventional flash memory provided with a redundancy circuit. As shown in FIG. 8, when the previous process is ended, a probe test is always performed for each wafer (step S101). If the number of defective sectors detected in a chip in the test is within a relievable range, a redundant relieving processing (fuse cut-off) is performed for the chip to replace each defective sector with a spare one (step S102). If the number of defective sectors detected in the chip exceeds the relievable range, the chip is removed when it is cut apart from the wafer. The fuse cut-off for adjusting both internal voltage and timing according to the result of the wafer test is also made together with the redundant relieving processing.

After that, the wafer is subjected to a dicing process in which chips are cut apart from the wafer, then each chip is sealed in a package (step S103). Each chip is then subjected to an aging (or burning-in) process to be tested with a high voltage applied thereto under a high temperature (step S104). A chip package, when it is decided to be normal, is mounted on a test board to be subjected to the final test with use of a tester (step S105). Management data referred to as an MGM code for denoting that the subject sector is normal is recorded in the sector management area of each sector that is decided to be normal (step S106) in the final test. After that, each chip is checked for whether or not the number of non-defective sectors is 98% of the total number of sectors and over. And, only the chips in which the number of non-defective sectors is 98% and over respectively are delivered as products (steps S107 and S108).

Furthermore, in each delivered flash memory, the MGM code is read from the sector management area by a flash controller provided in the user system to create an address translation table (step S109). While the flash memory is used in the user system repetitively, some sectors might become defective. If such a defective sector is detected, the flash controller rewrites the MGM code in the sector management area to register the defective sector address in the address translation table and replace the sector with another non-defective one (steps S110 and S111).

However, the test method for the conventional flash memories configured as described above cannot relieve any defective sector with use of the redundancy circuit after the delivery. Therefore, many spare sectors that are left over after a wafer test come to be left unused. As a result, wasteful parts are left over in each memory device. This has been a problem. In addition, in the subsequent processes for producing conventional flash memories, memory chips must be subjected to three tests that are a wafer test, an aging test, and a final test for packaged chips. And, it takes much time to deliver the flash memories and this results in increasing the test process cost. This has been a bottleneck for reducing the unit price of those chips.

Under such circumstances, it is an object of the present invention to provide a method for producing non-volatile semiconductor storage devices as flash memories, each of which enables information to be written/erased therein/therefrom electrically and the time for testing them before delivery to be shortened, thereby reducing the unit price of them.

It is another object of the present invention to provide a non-volatile semiconductor storage device free of address management that has been made by a controller, since defective sectors can be relieved even after the delivery with use of a redundancy circuit provided in the storage device.

These and other objects and novelty features of the present invention will becomes more apparent upon reading of the following detailed description and accompanying drawings.

### DISCLOSURE OF THE INVENTION

Typical aspects of the present invention disclosed in this specification will be summarized as follows.

According to one aspect of the present invention, in the method for producing a non-volatile semiconductor storage device provided with a memory array that includes a plurality of non-volatile semiconductor storage elements and a plurality of spare storage elements, each of which enables information to be written/erased therein/therefrom electrically, and configured so that each storage element decided to be defective in a normal write operation is replaced with one of the spare storage elements and information related to the defective storage element is stored in a predetermined area provided in the memory array, the information related to the defective storage element is not stored in the predetermined area provided in the memory array even when the defective storage element is detected in a test while the non-volatile semiconductor storage device is extracted as a non-defective product if the number of defective storage elements detected in the test is a predetermined value or lower.

According to the method described above, it is possible to omit wiring of information related to each defective storage element in the production process, so that the test process time can be reduced significantly.

The test described above should preferably be divided into two tests; one test is performed for each wafer from which chips are not cut apart yet while the other test is performed for the respective chips cut apart from the wafer as products. Consequently, the aging test or burning-in test is omitted, thereby the test process time can further be reduced.

According to another aspect of the present invention, in the method for producing a non-volatile semiconductor storage device provided with a memory array that includes a plurality of non-volatile storage elements and a plurality of spare storage elements, each of which enables information to be written/erased therein/therefrom electrically, and a trimming circuit for adjusting characteristics of an internal circuit, and configured so that the adjustment information of the trimming circuit is stored in a predetermined area provided in the memory array according to a result of a test while a storage element decided to be defective in a normal write operation is replaced with one of the plurality of spare storage elements and information related to the defective storage element is stored in the predetermined area provided in the memory array, adjustment information of the trimming circuit detected in the test is stored in predetermined area provided in the memory array while information related to a defective storage element detected in the test is not stored in the predetermined area provided in the memory array and each non-volatile semiconductor storage device is extracted as a non-defective product if the number of defective storage elements detected in the test is a predetermined value or lower. Consequently, it is possible to omit writing of the information related to each defective storage element in the production process, so that the process time can be reduced significantly.

The test described above should preferably be divided into two tests; one test is performed for a wafer from which chips are not cut apart yet and the other test is performed for the respective chips cut apart from the wafer as products. Consequently, the aging test or burning-in test can be omitted, thereby the test process time can be reduced.

According to still another aspect of the present invention, in the method for producing a non-volatile semiconductor storage device provided with a memory array that includes a plurality of non-volatile storage elements and a plurality of spare non-volatile storage elements, each of which enables information to be written/erased therein/therefrom electrically, and a trimming circuit for adjusting characteristics of an internal circuit, and configured so that adjustment information of the trimming circuit is stored in a predetermined area provided in the memory array according to a result of a test while a storage element decided to be defective in a normal write operation is replaced with one of the spare storage elements and the information related to the defective storage element is stored in a predetermined area provided in the memory array, the adjustment information of the trimming circuit detected in a test performed for a wafer from which chips are not cut apart yet and information of a defective storage element detected in the test performed for the respective chips cut apart from the wafer are stored in a predetermined area provided in the memory array, then an aging or burning-in test is performed for the respective cut-apart chips, then another test is performed for them so that the adjustment information of the trimming circuit detected in the test and the information related to each defective storage element detected in the test are stored in the predetermined area provided in the memory array. Consequently, the method comes to provide highly reliable non-volatile semiconductor storage devices.

In this case, each storage device should preferably be extracted as a non-defective one if the number of unused spare storage elements except for those that take the places of the defective storage elements according to the test performed for the respective chips is a predetermined value or higher. A certain number of defective storage elements generated newly during a normal operation can thus be relieved, thereby the method comes to provide non-volatile semiconductor storage devices with higher reliability.

According to still another aspect of the present invention, in a non-volatile semiconductor storage device provided with a memory array that includes a plurality of non-volatile storage elements and a plurality of spare storage elements, each of which enables information to be written/erased therein/therefrom electrically, and configured so that information related to each defective one of the plurality of non-volatile storage elements is stored in a predetermined area provided in the memory array, the storage device is configured to further include a volatile storage circuit for retaining information related to each defective storage element of the plurality of non-volatile storage elements during an operation, an address comparison circuit for comparing information retained in the storage circuit with inputted address information, and a selection circuit for selecting one of the plurality of spare storage elements according to an output from the address comparison circuit.

In the non-volatile semiconductor storage device configured as described above, information of each defective storage element is stored in another non-volatile storage element, thereby the information is retained even when the storage device power is turned off. The reliability of the storage device is thus more improved. In addition, the information related to each defective storage element is retained in a non-volatile storage circuit, so that when a defective storage element is accessed, the information related to the defective storage element is transferred quickly to the address comparison circuit that makes comparison between addresses so as to switch an accessed defective storage element over to a spare one, thereby reading/writing information from/in the storage device is made faster.

Furthermore, the above storage device is provided with a trimming circuit for adjusting characteristics of an internal circuit and adjustment information of the trimming circuit is stored in a predetermined non-volatile area provided in the memory array while the adjustment information of the trimming circuit that is active is stored in the non-volatile storage circuit. Consequently, the adjustment information of the trimming circuit can be read out faster.

Furthermore, the non-volatile storage circuit retains inputted address information. If information cannot be written in any of the plurality of non-volatile storage elements during an operation, the defective storage element is replaced with one of the plurality of spare storage elements, then information is written in the spare storage element while the address information retained in the volatile storage circuit is transferred to and stored in the predetermined area provided in the memory array. Consequently, if the spare storage element that has taken the place of the defective one becomes defective, it is further replaced with another spare one. As a result, the reliability of the storage device is further improved.

Furthermore, if the spare non-volatile storage element that takes the place of the defective storage element is defective, the address information retained in the non-volatile storage circuit is invalidated. Consequently, reading/writing wrong data from/in the storage elements is prevented and a replacement circuit for replacing each defective storage element with a spare one can be configured in a rational manner.

### BRIEF DESCRIPTION OF THE DRAWINGS

FIG. 1 is a block diagram of a flash memory used as a semiconductor storage device in an embodiment of the present invention;

FIG. 2 is a timing chart of data transfer from a fuse sector in a memory array to a buffer memory provided respectively in the flash memory in the embodiment of the present invention;

FIG. 3 is a flowchart of a procedure executed by a sector management controller for sector management so as to write data in the flash memory in the embodiment of the present invention;

FIG. 4 is a schematic circuit diagram of the memory array;

FIG. 5 is concrete circuit diagrams of the buffer memory and the address comparator provided respectively in the flash memory in the embodiment of the present invention;

FIG. 6 is a flowchart of one of the redundant reliving procedures executed for highly reliable products in the flash memory of the present invention;

FIG. 7 is a flowchart of one of the redundant relieving procedures executed for low-price products in the flash memory of the present invention;

FIG. 8 is a flowchart of a defective sector relieving procedure executed for a conventional flash memory;

FIG. 9 is an illustration for a defective sector relieving method with use of a controller and another defective sector relieving method with use of a redundancy circuit employed respectively for the conventional flash memory;

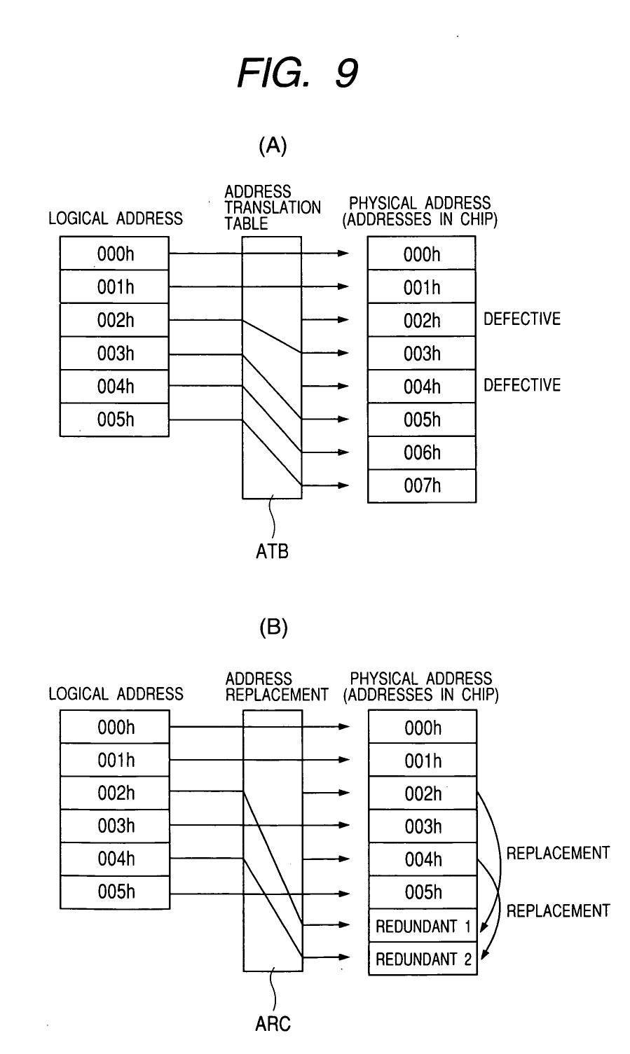

FIG. 10 is a block diagram of a memory card that is actually the flash memory of the present invention; and

FIG. 11 is a flowchart of a write processing procedure executed by a flash controller provided in the memory card that is actually the flash memory of the present invention.

### BEST MODE FOR CARRYING OUT THE INVENTION

Hereunder, the preferred embodiment of the present invention will be described with reference to the accompanying drawings.

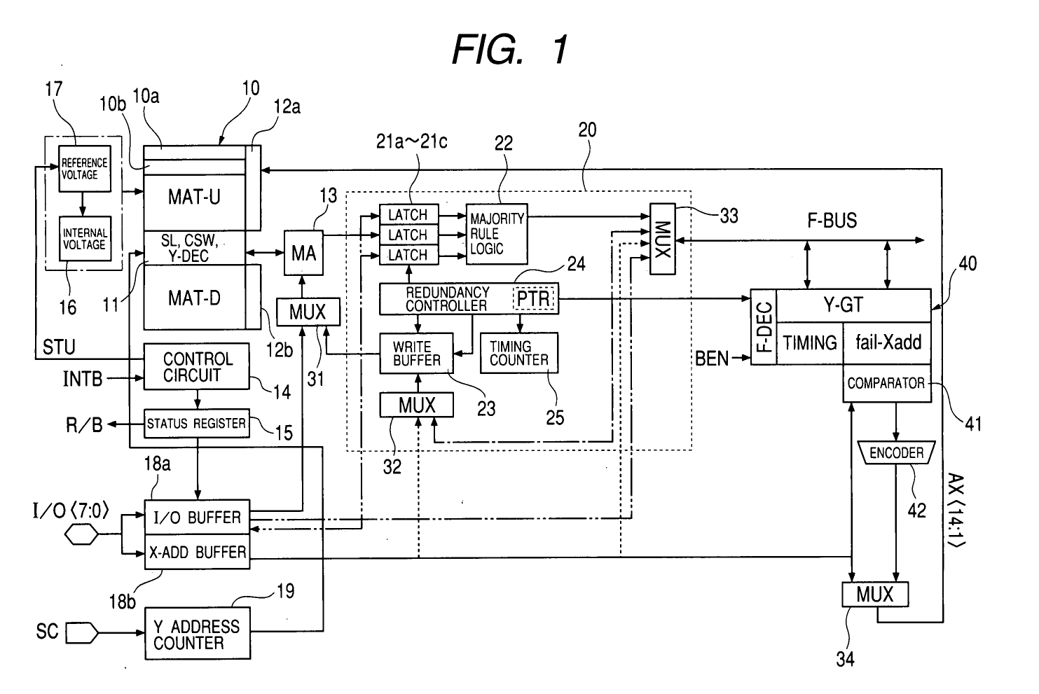

FIG. 1 shows a block diagram of a flash memory as an example of a non-volatile semiconductor storage device in the embodiment of the present invention. There is a multi-level memory usable as a flash memory. The multi-level memory can store data consisting of 2 or more bits in one memory cell. However, the flash memory in this embodiment is a binary memory that can store single-bit data in one memory cell. The flash memory is formed on one semiconductor chip formed with, for example, single crystallization silicon.

Although the flash memory is provided with only one memory array in this embodiment, the flash memory may also be provided with a plurality of such memory arrays so as to be formed as a memory composed of banks.

In FIG. 1, reference numeral 10 denotes a memory array in which a plurality of non-volatile storage elements are disposed like a matrix. The memory array 10 in this embodiment is composed of two memory mats MAT-U and MAT-D. Between those two memory mats are disposed a sense latch SL connected to the bit line of each memory mat and used to retain write data, as well as amplify and latch read signals, a column decoder Y-DEC for decoding each Y address to generate a signal for selecting a bit line, and a column switch C-SW used for the connection between the sense latch SL and a main amplifier (MA) according to the select signal generated in the column decoder Y-DEC. In FIG. 1, the sense latch SL, the column decoder (Y decoder) Y-DEC, and the column switch C-SW are included in one functional block 11.

The memory array 10 includes X address decoders (X decoders) 12a and 12b corresponding to the memory mats MAT-U and MAT-D. Each of the decoders 12a and 12b includes a word drive circuit for driving a word line in the corresponding memory mat into a selected level according to a result of decoding.

The memory mat MAT-U, one of the two memory mats provided in the memory array 10, is provided with a normal memory row and an alternate spare memory row (hereinafter, to be referred to as a redundant sector) 10a separately from its original memory row and a sector (hereinafter, to be referred to as the fuse sector) 10b for storing a defective sector address and trimming information. In this specification, memory cells connected to one word line is referred to as a sector generically. Although not limited specially, in the flash memory in this embodiment, data is written in sectors.

Furthermore, although not limited specially, the flash memory in this embodiment is also provided with a controller 14 for interpreting commands received from external microprocessors, etc to generate for and output control signals to each circuit provided in the memory sequentially so as to execute processings in accordance with those commands, as well as a status register 15 for denoting the status in the chip.

The controller 14 is configured, for example, by a ROM (Read Only Memory) for storing a series of micro-commands required to execute a command and a command decoder for decoding such a series of micro-commands read from therefrom to generate control signals for each circuit in the chip. The controller 14 may be configured so as to decode each command and execute a processing corresponding to the command automatically when receiving the command through one of external terminals 1/o 0 to 7.

Furthermore, the flash memory in this embodiment is further provided with an internal voltage generation circuit 16 for generating a step-up voltage used to write/erase information therein/therefrom and a reference power supply circuit 17 for generating a reference power required to generate a predetermined voltage in the internal voltage generation circuit 16. Reference numeral 18a denotes an input/output buffer circuit for fetching write data signals and commands inputted through external terminals I/O 0 to 7 and outputting data signals read from the memory array and reference numeral 18b denotes an address buffer circuit for fetching row address signals inputted through the external terminals I/O 0 to 7. Although not limited specially, the content in the status register 15 is output by the input/output buffer circuit 18a through the external terminals I/O 0 to 7.

Furthermore, reference numeral 19 denotes a Y address counter for generating consecutive column addresses (Y addresses) and counting the addresses according to the clock signal SC supplied from external. The generated Y addresses are supplied to the column decoder Y-DEC and the column switches CSW in the memory array 10 are turned on sequentially to select bit lines. Other reference numerals in FIG. 1 are defined as follows; 20 denotes a defective sector management circuit for managing defective sectors detected in the memory array, 31 to 34 denote multiplexers for selecting data to be transmitted respectively, and 40 denotes a buffer memory formed with an SRAM and used to retain such data as defective sector addresses and trimming information stored in the redundant sector area 10a and the fuse sector area 10b provided respectively in the flash memory array 10.

The defective sector management circuit 20 is configured by three latch circuits 21a to 21c for retaining data read from the memory array 10, a majority rule logic circuit 22 for making majority decision for the read data latched in the latch circuits 21a to 21c, a write buffer 23 for retaining data to be written in the fuse sector area 10b, a redundancy controller 24 for controlling the operation of the defective sector management circuit 20, a timing counter 25 for generating timing signals required for the operation of the defective sector management circuit 20.

Control signals inputted to the flash memory in this embodiment from external devices such as an external CPU are, for example, the reset signal, the chip select signal, the write control signal, the output control signal, and the command enable signal for distinguishing among a command, a data input, and an address input, and the system clock SC. Both commands and addresses may be fetched into the input/output buffer circuit 18a and the address buffer circuit 18b according to, for example, the command enable signal and the write control signal. Write data may be fetched into the input/output buffer circuit 18a synchronously with the system clock SC inputted from external when the command enable signal denotes a command or data input.

In addition to the buffer memory 40, the flash memory in this embodiment is also provided with an address comparison circuit 41 for deciding whether or not each defective sector address retained in the buffer memory 40 matches with a row address inputted from external and an encoder 42 for encoding an output from the address comparison circuit 41 to generate a redundant sector address that specifies a redundant sector in the redundant sector area 10a.

The reason why the defective sector management circuit 20 is provided with the majority rule logic circuit 22 is to assure the reliability of data read from the fuse sector area 10b provided in the flash memory array 10. In that connection, three sets of the same data (trimming information and a defective sector address) are stored in the fuse sector area 10b beforehand. And, those three data sets are read continuously to be latched in the latch circuits 21a to 21c, then normal data is decided by majority in the majority rule logic circuit 22 and the normal data is transferred to the buffer memory 40 through the multiplexer 33 to be stored there. Those sets of data stored in the fuse sector area 10b are read from the memory array 10 when the storage device is powered and stored in the buffer memory 40.

It takes much time to read data from the memory array 10, since the memory array 10 is composed of non-volatile storage elements. To avoid this problem, data is transferred to the buffer memory 40 formed with an SRAM beforehand and retained there, so that the data can be referred to quickly as needed. Especially, defective sector address information is needed to decide whether or not a sector to be accessed is defective when in writing/reading data therein/therefrom according to an address signal inputted from external. If it takes much time to read this defective sector address, it also takes much time to access the data. In the flash memory in this embodiment, however, each defective sector address is copied in the buffer memory 40 beforehand, so that the defective sector address can be compared with an address inputted from external immediately when the address is inputted.

Furthermore, because the buffer memory 40 stores addresses inputted from external, the buffer memory 40 also functions as an address retaining circuit for retaining the address for the position of each detected defective sector. Each address retained in this buffer memory 40 is transferred to the write buffer 23 through the multiplexer 32 each time a defective sector is detected. The redundancy controller 24 of the defective sector management circuit 20 is used for this address transfer.

The defective sector address retaining area provided in the buffer memory 40 retains the number of addresses corresponding to the number of redundant sector areas 10a provided in the memory array 10. Each defective sector address retaining area is pointed by a pointer PTR held in the redundancy controller 24. This pointer PTR, which points one of the defective sector address retaining areas provided in the buffer memory 40 directly, also functions as a pointer that points a redundant sector indirectly, since each defective sector address retaining area corresponds to a redundant sector in the redundant sector area 10b provided in the memory array 10 at a one-to-one correspondence.

The redundancy controller 24, when it finds a detected defective sector from the value set in the status register 15, transfers the defective sector address retained in the buffer memory 40 to the write buffer 23 provided in the redundant sector management circuit 20, then writes the defective sector address in consecutive three places in the fuse sector area 10b provided in the memory array 10. At this time, the redundancy controller 24 may also transfer all the addresses retained in the buffer memory 40 to the write buffer 23, then write them in the fuse sector area 10b provided in the buffer memory 40.

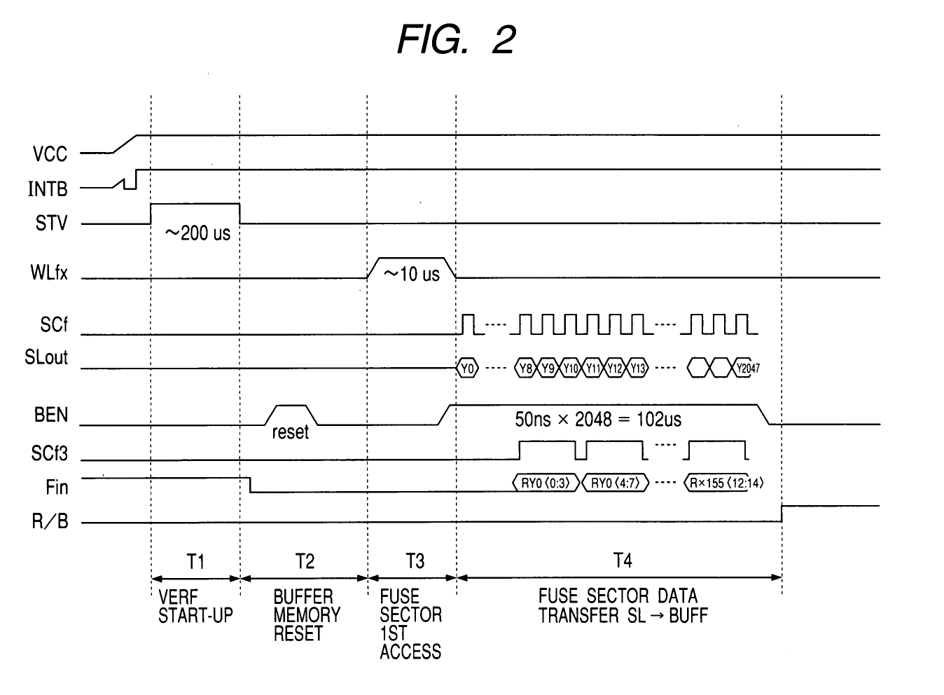

FIG. 2 shows a timing chart of the processings for transferring a defective sector address read from the fuse sector area 10b provided in the memory array 10 to the buffer memory 40. As shown in FIG. 2, a defective sector address is transferred to the buffer memory 40 when the storage device is powered.

If the supply voltage Vcc rises, thereby the supply voltage detection signal INTB is supplied to the controller 14 from a power supply detection circuit (not shown), the controller 14 drives the setup signal STV to be supplied to the reference power supply circuit 17 into High level for a predetermined period. Then, the reference power supply circuit 17 is activated to generate a reference power supply. According to this reference power supply, the internal power supply circuit 17 begins to generate and supply an internal supply voltage to a predetermined circuit provided in the chip (for the T1 period in FIG. 2). After that, the level of the activation signal BEN supplied to the buffer memory (SRAM) from the redundancy controller 24 is driven into High temporarily. At this time, because the data input terminal is Low in level, the buffer memory 40 is reset (in a period of T2 in FIG. 2).

Then, the level of the word line WLfx of the fuse sector area 10b provided in the memory array 10 is changed to High, so that the data set (trimming information and a defective sector address) stored in the fuse sector area 10b is transferred to the sense latch SL and amplified there (in a period of T3 in FIG. 2).

After that, the data in the sense latch SL is transferred to the main amplifier 13 synchronously with the clock SCf inputted from the timing counter 25 and amplified there, thereby consecutive three sets of data are latched in the latch circuits 21a and 21c sequentially. And, the data sets are subjected to a process of decision by majority performed in the majority rule logic circuit 22, then the selected majority data is transferred to the buffer memory (SRAM) 40 to be retained there (in the T4 period in FIG. 2).

Hereinafter, the data retained in the buffer memory (SRAM) 40 is usable. Then, for example, “1” is set in the bit (Ready/Busy) R/B in the status register 15, which denotes the status of the chip, thereby reporting to the subject external device that the chip is now ready to be accessed. At the starting time of operation, the redundancy controller 24 can decide and set the value of the pointer PTR by counting the number of valid defective sector addresses read from the fuse sector area 10b and transferred to the buffer memory (SRAM) 40.

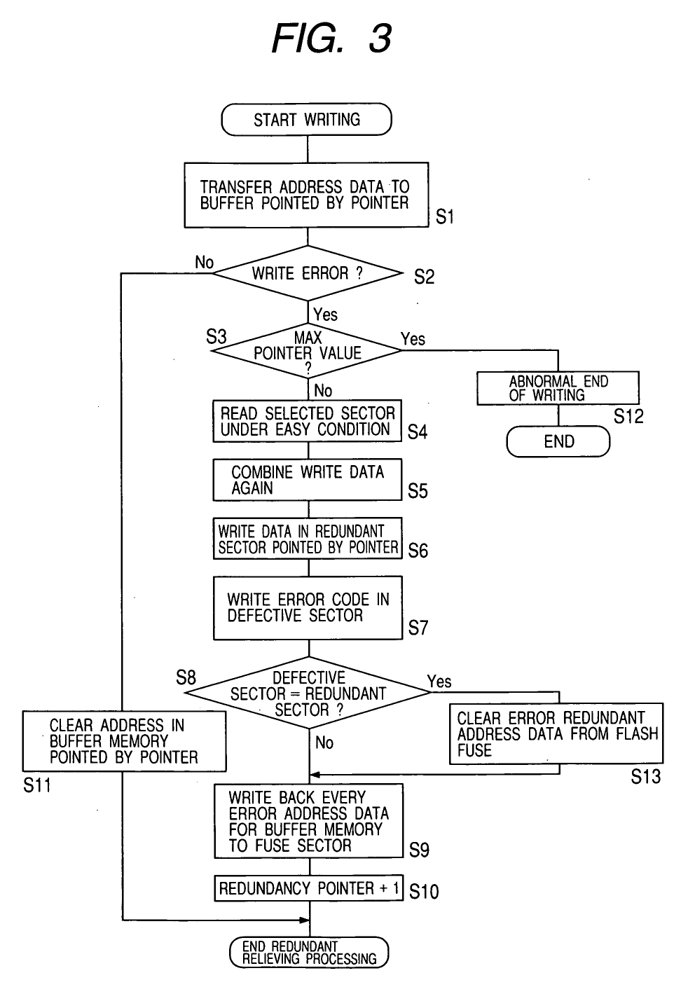

Next, a description will be made for defective sector relieving processings performed in the flash memory in this embodiment with reference to the flowchart shown in FIG. 3. The processings in this flowchart are controlled by the redundancy controller 24 provided in the defective sector management circuit 20. These defective sector relieving processings can be executed in both flash memory test and normal operation.

At first, a write command, a write address, and write data are inputted to the chip from external, then a write start command is inputted to the chip. Then, the control flow shown in FIG. 3 begins. Consequently, the controller 24 supplies the write address inputted from external and fetched in the row address buffer 18b to the corresponding one of the row address decoders 12a and 12b provided in the memory array 10 through the multiplexer 34 and stores it in a defective sector address retaining area provided in the buffer memory 40 and pointed by the pointer PTR (step S1) through the multiplexer 33. The write command is supplied to the controller 14 and the write data is supplied to the main amplifier 13 from the input/output buffer 18a respectively, thereby data is written in the sector specified by the write address in the memory array 10.

After that, the controller 24 decides whether or not the writing is ended normally (step S2). After the normal end of the writing, the chip controller 14 verifies the written data and sets the result in the status register 15. This status register 15 can be checked to decide whether or not the writing is ended normally. Concretely, if the read data and the written data do not match with each other in the verification, “1” (Fail) is set in the check bit provided in the status register 15, for example. If they match with each other, “0” (Pass) is set in the check bit. This is why the controller can check whether or not the writing is ended normally according to the value set in the check bit for denoting Fail or Pass.

If the decision in step S2 results in YES (normal), control goes to step S11 in which the controller 24 clears the address data in the buffer memory 40 pointed by the pointer PTR and exits the writing. However, if the buffer memory 40 is configured so that old data is overwritten with new data and the new data is stored therein correctly, the writing may be ended with no operation.

If the decision in step S2 results in NO (abnormal), control goes to step S3 in which the controller 24 decides whether or not the maximum value is set in the pointer PTR. The maximum value of the pointer PTR matches with the number of replaceable redundant sectors. When the pointer PTR reaches the maximum value, it denotes that there is no redundant sector that will take the place of any defective sector. Consequently, if the pointer PTR reaches the maximum value, control goes to step S12 in which the controller 24 decides that the writing is disabled. Consequently, the controller 24 sets “1” in the abnormal end bit (error bit) provided in the status register 15 and exits the writing.

If the decision in step S3 results in NO (not maximum), control goes to step S4 in which the controller 24 lowers the level of the work line selection than the verification level to read the target data. In a flash memory, the threshold voltage of a memory cell, when it must be changed, usually comes to be changed almost up to the verification level, so that the word line selection level can be lowered to read data, thereby transferring the same data as that handled when in normal writing to the sense amplifier.

However, in a flash memory in which a logic value “0” corresponds to the erasure state having a high threshold value while the threshold voltage of memory cells corresponding to the write data having a logic value “1” is lowered, the logic of the read data to be verified and that of the write data are inverted from each other. This is why the read data retained in the sense latch SL is inverted in state in the next step S5, thereby written data is combined again to restore the original data.

In the next step S6, the controller 24 writes the recombined written data retained in the sense latch SL in the redundant sector 10a provided in the memory array 10 corresponding to the defective sector address retaining area in the buffer memory 40, pointed by the pointer PTR. This processing is to write data in a redundant sector that has took the place of a decided defective memory cell. The reason why data is written in a redundant sector corresponding to a defective sector address retaining area of the buffer memory 40 pointed by the pointer PTR is that the redundant sector corresponding to the previous value of the current specified one set in the pointer PTR is already used, that is, it is already replaced with a normal sector.

Then, in step S7, the controller 24 writes a normal or abnormal code other than the MGM one in the sector management area of the sector decided to be defective in a write operation in step S2.

The above processings are all executed to replace a sector with another according to a stored defective sector address during a normal operation in the flash memory. According to this procedure, each detected defective sector address is transferred to the write buffer 23 from the buffer memory 40, then stored in the memory array 10 through the main amplifier 13. However, each defective sector address detected in a test performed for each wafer may also be stored in the storage device provided in the tester beforehand, then it is supplied to the memory array 10 through the same route as that of ordinary write data, that is, from the input/output buffer 18a to the memory array 10 through the main amplifier 13.

In the next step S8, the controller 24 decides whether or not the sector decided to be defective in the write operation in step S2 is a redundant one. In other words, the controller 24 checks whether or not a normal sector in which writing is done is decided to be defective, the sector is replaced with a redundant one and writing is done again in the sector, then the sector is decided to be defective again. Such a decision is made so as to cope with even a case in which a redundant sector itself is decided to be defective.

If the decision in step S8 results in YES (redundant sector), control goes to step 13 in which the controller 24 clears the address data corresponding to the defective sector from the buffer memory 40. If the address data is kept left in the buffer memory 40 as it is, it is regarded as a defective sector address in the fuse sector area 10b provided in the memory array 10, thereby the address is copied into the buffer memory 40 again when the storage device is powered and a corresponding redundant sector (decided to be defective in step S8) comes to be selected. This is why the address is cleared from the buffer memory 40 to avoid such a trouble. The address data cleared from the buffer memory 40 comes to be retained in another area in the buffer memory 40 when data is written in the address again after a write error.

After the address data corresponding to the defective sector is cleared from the buffer memory 40 in step S13 or if the defective sector is not decided to be redundant in step S8, control goes to step S9 in which the controller 24 writes every address stored in the buffer memory 40 in the fuse sector area 10b provided in the memory array through the write buffer 23.

Consequently, the controller 24 comes to write the address of the new redundant sector that has taken the place of a defective one or value cleared in step S13 in the fuse sector area 10b. In other words, the controller 24 adds a defective sector address to the fuse sector area 10b or if the defective sector is a redundant sector, the controller 24 clears the address of the defective sector written in the fuse sector area 10b. After that, control goes to step S10 in which the controller 24 updates the redundant sector pointer PTR (+1) and exits the write processing.

Ending the defective sector relieving processing in the above procedure, the chip controller 14 executes verification to check whether or not the writing is ended normally. At this time, the external CPU can know the result of the writing by checking a predetermined bit (ex., write check bit) in the status register according to the decision result of the chip controller 14. And, if the defective sector is decided as a redundant sector in step S8 and the writing is ended, “FAIL” is set in the check bit in the status register. Consequently, the CPU decides that the writing is not ended yet according to the result of the reference to the check bit. If the error bit in the status register does not denote the “ERROR” status, the CPU can retry the writing in the same address. At this time, in the redundant sector management circuit 20, the redundancy pointer PTR in the controller 24 is already updated. In other words, the pointer PTR points another redundant sector. Therefore, even when data is written in the same address again and the sector is decided to be defective, the sector comes to be replaced with the pointed redundant sector in the defective sector relieving processing as shown in FIG. 3 .

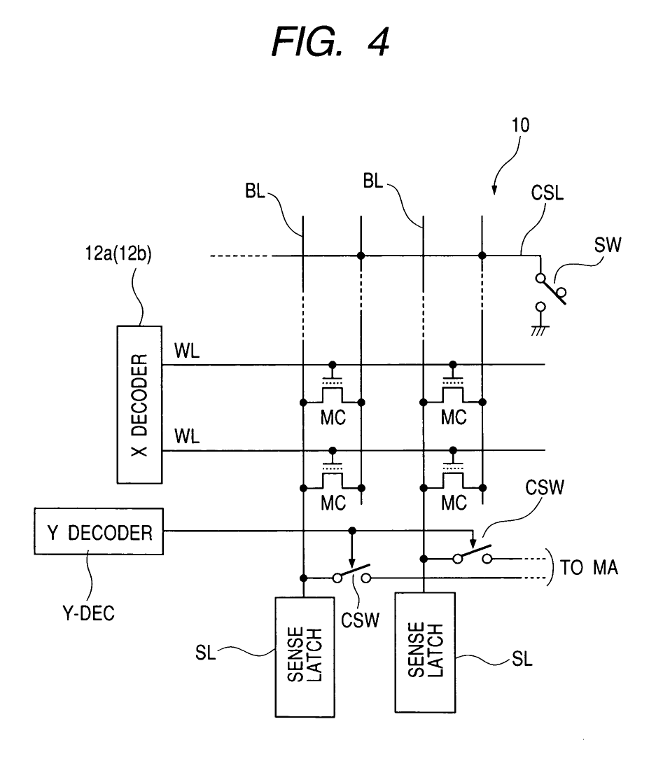

FIG. 4 shows a schematic block diagram of the memory array 10. In the memory array 10, a plurality of memory cells MC are disposed like a matrix and each word line WL connected to the control gates of the memory cells in the same row and each bit line BL connected to the drains of the memory cells in the same column are disposed so as to cross each other. The source of each memory cell is connected to a common source line CSL that outputs a ground potential. The common source line CSL has a switch SW for opening the source of the memory cell when in writing.

A sense latch circuit SL provided with a sense amplifying function for amplifying the potential of a corresponding bit line and a data retaining function is connected to one end of each bit line BL. The sense latch circuit SL is also provided with a switch element for connecting/disconnecting the corresponding bit line electrically and means for discharging the bit line.

The sense latch circuit is also provided with an inversion circuit for inverting the logic of data on the bit line. This inversion circuit makes it possible to invert the logic of data on the bit line even when the logic of write data and the logic of data read from each memory cell are inverted from each other.

Although not particularly limited, the flash memory in this embodiment may be configured as follows. Concretely, a positive high voltage (ex., +16V) is applied to the word line WL (control gate) when in writing to make most use of the FN tunnel phenomenon, thereby charging the floating gate of the memory cell negatively to increase the threshold voltage thereof. Consequently, the bit line BL is not precharged when it is connected to a memory cell (ex., “1” is written therein) in which the threshold voltage is to be increased, that is, 0V is applied thereto. On the other hand, a bit line BL connected to a memory cell in which the threshold voltage is not to increase (ex., “0” is written therein) is precharged to 5.5V. When in writing of data, the source of each selected memory cell is set in the floating (open) state. When in erasing of data, a negative high voltage (ex., −16V) is applied to the word line WL (control gate) and 0V is applied to both of the bit line BL and the source line SL to cause an FN tunnel phenomenon, thereby the subject memory cell is discharged negatively from the floating gate to lower the threshold voltage.

Table 1 shows configuration data set in the status register 15 in the embodiment of the present invention.

TABLE 1

| | Definition | | |
|---|---|---|---|
| B7 | Ready/Busy | Busy | Ready |
| B6 | Error bit | Safe | Error |
| B5 | Erasure | Normal | Abnormal |
| | check | | |
| B4 | Write check | Normal | Abnormal |
| B3 | Reserved | — | — |
| B2 | Reserved | — | — |
| B1 | Reserved | — | — |
| B0 | Reserved | — | — |

The status register 15 in this embodiment consists of 8 bits B7 to B0. The bit B7 (hereinafter referred to as R/B bit) denotes the internal control state of the chip, the bit B6 (error bit) denotes whether or not a subject write operation is ended abnormally, the bit B5 (erasure check bit) denotes an erasure operation result, the bit B4 (write check bit) denotes a write operation result, and bits B3 to B0 are reserved.

Concretely, the bits B7 to B0 may be defined as follows: The logic value “0” of the bit B7 denotes that the chip is operating, thereby it cannot be accessed from external. The logic value “1” of the bit B7 denotes that the chip stands by, so that it can be accessed from external. The logic value “0” of the bit B6 denotes a possibility that the subject writing may be done successfully with a write command to be inputted next. The logic value “1” of the bit B6 denotes that no writing is permitted. In addition, the logic value “0” of the bit B5 denotes that an erasure operation is ended normally while the logic value “1” of the bit B5 denotes that the erasure is not ended normally. The logic value “0” the bit B4 denotes that the subject writing is ended normally while the logic value “1” the bit B4 denotes that the writing is not ended normally.

Among the bits B7 to B0 of the status register 15, the state of the R/B bit B7 is always output from the external terminal. For example, the states of all the bits B7 to B0 are output from the input/output terminals I/O7 to I/0 when both of the chip enable signal and the out enable signal supplied from external are asserted to Low in level. In addition, the chip controller 14 sets each of the bits B7 to B0 in the status register 15 sequentially according to how the chip is to be controlled.

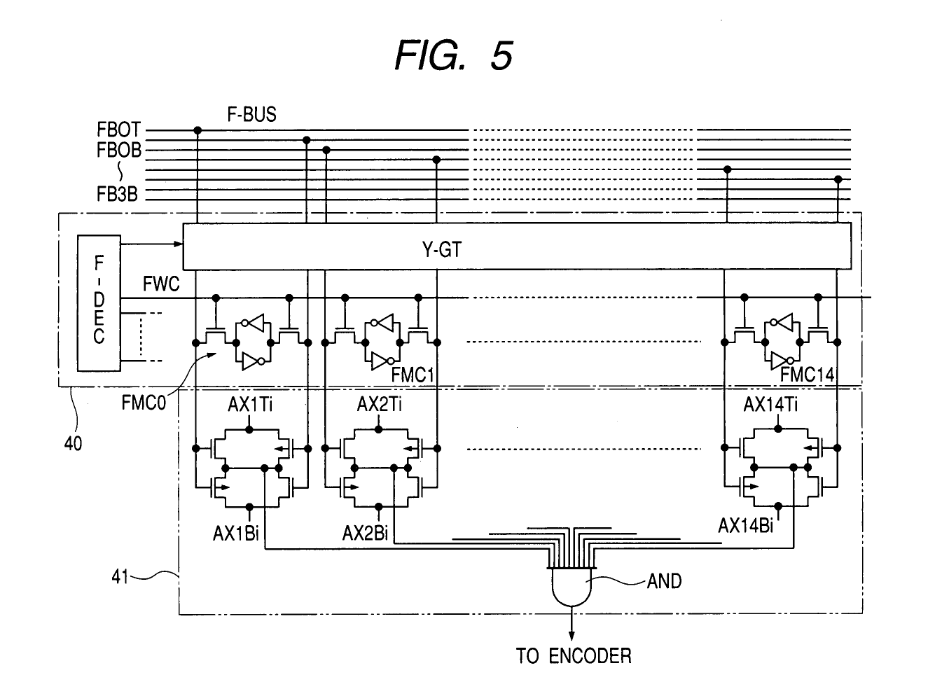

FIG. 5 shows concrete circuit examples of both buffer memory 40 and comparator 41.

As shown in FIG. 5, the buffer memory 40 is configured by the same cells as those of the well-known SRAM. One word line FWL is connected to 15 memory cells FMC0 to FMC14 and configured so as to store 15-bit address data and trimming data.

In FIG. 5, only a memory array equivalent to the space of one data item is shown. Actually, however, a plurality of memory arrays are provided in the buffer memory 40 in accordance of the number of data items to be stored in the memory 40. F-BUS denotes an internal bus used for the connection between the buffer memory 40 and the defective sector management circuit 20. Although not particularly limited, the internal bus F-BUS consists of eight signal lines FB0T, FB0B to FB3T, and FB3B. The internal bus F-BUS can transfer 4-bit data in parallel in response to a differential signal.

Between the internal bus F-BUS and the memory array of the buffer memory 40 is provided a Y gate Y-GT that is equivalent to a column switch in function, as well as a decoder F-DEC for opening/closing the Y gate Y-GT selectively by decoding the value of the pointer PTR provided in the redundancy controller 24. This decoder F-DEC has functions for controlling the Y gate Y-GT and decoding the value of the pointer PTR to select one word line FWL in the buffer memory 40. And, the decoder F-DEC controls the Y gate Y-GT to store data in the memory cells FMC0 to FMC14 connected to the selected word line of the buffer memory 40 from the internal bus F-BUS, 4 bits at a time and 4 times, in a time division manner. Similarly, when transferring data to the write buffer 23 provided in the defective sector management circuit 20 from the buffer memory 40, the decoder F-DEC also decodes the value of the pointer PTR to control the Y gate Y-GT and enable one word line FWL in the buffer memory 40 to be selected so as to read and transfer data to the internal bus F-BUS in a time division manner.

The comparator 41 is configured by 15 unit comparators CMP0 to CMP14 corresponding to the 15 memory cells FMC0 to FMC14 and a multi-input logic product gate AND that receives outputs of the unit comparators CMP0 to CMP14. And, a plurality of comparators configured in such a way are provided in the buffer memory 40 in accordance with the number of defective sector addresses to be stored in the memory 40. The output of the multi-input logic product gate AND is supplied to the encoder 42 and encoded there. Concretely, for example, if the buffer memory 40 can store 8 defective sector addresses, 8 outputs of the 8 multi-input logical product gates AND are encoded by the encoder 42 to generate 3-bit redundant sector address signals to be supplied to the X decoder 12a provided in the flash memory array 10.

The trimming information retained in the buffer memory 40 is supplied to the trimming circuit (not shown) without passing any comparator and used to adjust the voltage in the internal voltage generation circuit 16 and the timing of each control signal in the timing counter 25.

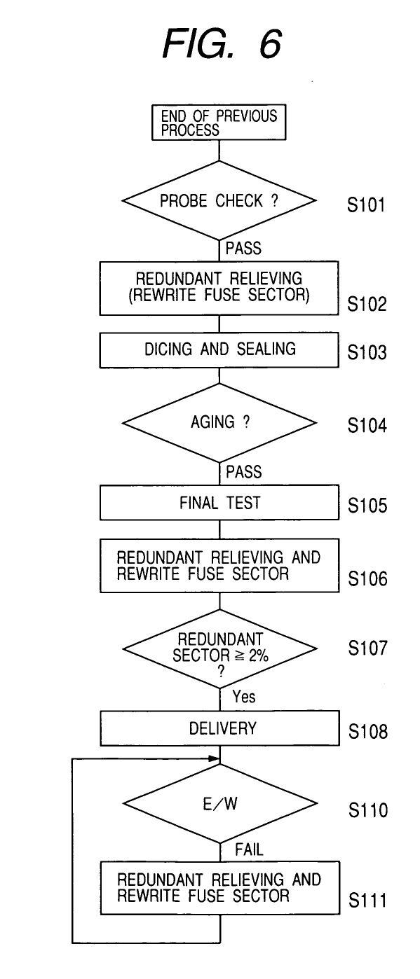

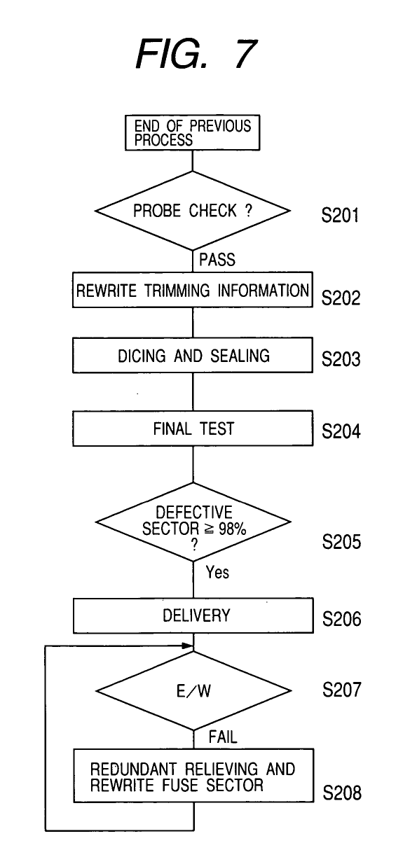

FIG. 6 shows one of the redundant relieving procedures employed in the flash memory of the present invention. The selected procedure shown in FIG. 6 applies to highly reliable products. FIG. 7 shows another redundant relieving procedure to be applied to low-price products.

In the redundant relieving of highly reliable products, as shown in FIG. 6, a probe test is performed for each wafer just after the previous process is completed (step S101). If the number of defective sectors detected in this test is within a relievable range, a redundant relieving processing is performed so that the addresses of the detected defective sectors are written in the fuse sector 10b and the defective sectors are replaced with spare sectors (step S102). This processing is referred to as a redundant relieving processing. If the number of detected defective sectors in a chip exceeds the relievable range, the chip is removed as a defective one when it is cut apart from the wafer. Writing of the defective sectors in the fuse sector 10b so as to set the trimming information according to the result of the wafer test is also done together with the redundant relieving processing.

After that, the wafer is cut into chips (dicing) and each cut-off chip is sealed in a package (step S103). Then, each chip is subjected to an aging process (or burning-in process) in which a high voltage is applied to the chip under a high temperature (step S104). Each chip decided to be normal is mounted on a test board and subjected to the final test with use of a tester (step S105).

If any relievable defective sector is detected in this final test, the defective sector address is written in the fuse sector 10b (redundant relieving) to replace the defective sector with a spare one (step S106). If the trimming information must be changed as a result of the final test, the trimming information is also written in the fuse sector 10b upon execution of the redundant relieving processing. After that, it is checked whether or not the remaining space of the unused redundant sector area 10a is equal to or more than 2% of the total. And, only the chips in which the remaining area 10a is equal to or more than 2% respectively are delivered as products (steps S107 and S108).

Furthermore, in the flash memory of the present invention, if a defective sector is detected when in writing/erasing of data in/from the user system after delivery, the defective sector management circuit 20 provided in the flash memory rewrites the data in the fuse sector 10b to replace the defective sector with a redundant one (additional redundant relieving) (steps S110 and S111).

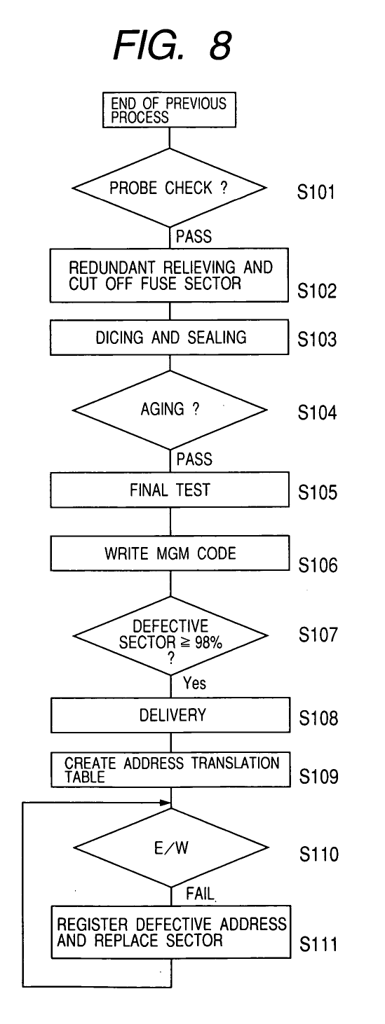

As will be understood clearly from the result of comparison with the redundant relieving method of the conventional flash memory shown in FIG. 8, the flash memory of the present invention can omit creation of the address translation table in step S109 and the sector management that uses this address translation table. Conventionally, a flash controller has been used for both address translation table creation and sector management while the flash memory of the present invention uses the defective sector management circuit 20 provided therein for rewriting the fuse sector area 10b to realize the additional redundant relieving as described above. The flash controller can thus be omitted from the system, thereby the system build-up cost is reduced.

On the other hand, in each of the low-price product test and the redundant relieving process for low-price products, a probe test is performed for each wafer just after the previous process is ended as shown in FIG. 7 (step S201). At this time, no redundant relieving processing is done even when a defective sector is detected in the test, although the defective sector address is written in the fuse sector 10b so as to set the trimming information according to the result of the wafer test (step S202).

After that, the wafer is subjected to a dicing process in which the wafer is cut into chips, then to a sealing process in which each cut-off chip is sealed in a package (step S203). The aging test is skipped here and a final test is performed for the respective chips with use of a tester (step S204). No redundant relieving processing is done here even when a defective sector is detected in this final test while it is checked whether or not the number of non-defective sectors in the memory array 10 is 98% or more of the total number of sectors therein according to the result of this final test. And, only the chips that pass this check (the rate of the non-defective sectors is 98% or more) are to be delivered as products (steps S205 and S206).

After the delivery, writing and erasing tests are performed in the user system. And, if any defective sector is detected during any of the tests, the defective sector management circuit 20 provided in the flash memory rewrites the defective sector address in the fuse sector area 10b to perform a redundant relieving processing (steps S207 and S208).

As will be understood clearly from the comparison with the redundant relieving process of highly reliable products shown in FIG. 6, the redundant relieving process for the low-price flash memories can omit all of the redundant reliving processing performed by writing defective sector addresses in step S101, the aging test in step S104, and the redundant reliving processing performed by writing defective sector addresses in step S106. Consequently, the time that has been required for those tests and redundant relieving processings is reduced significantly.

The reason why the aging test in step S104 can be omitted is that the flash memory provided with a defective sector management circuit and a buffer memory for retaining defective sector addresses as described in the above embodiment can perform a redundant relieving processing for replacing each defective sector detected during an operation with a spare one during the operation.

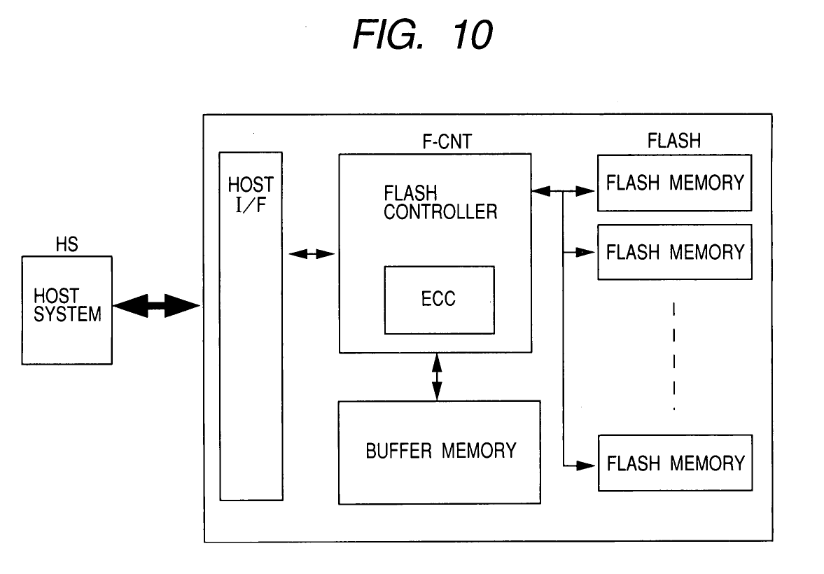

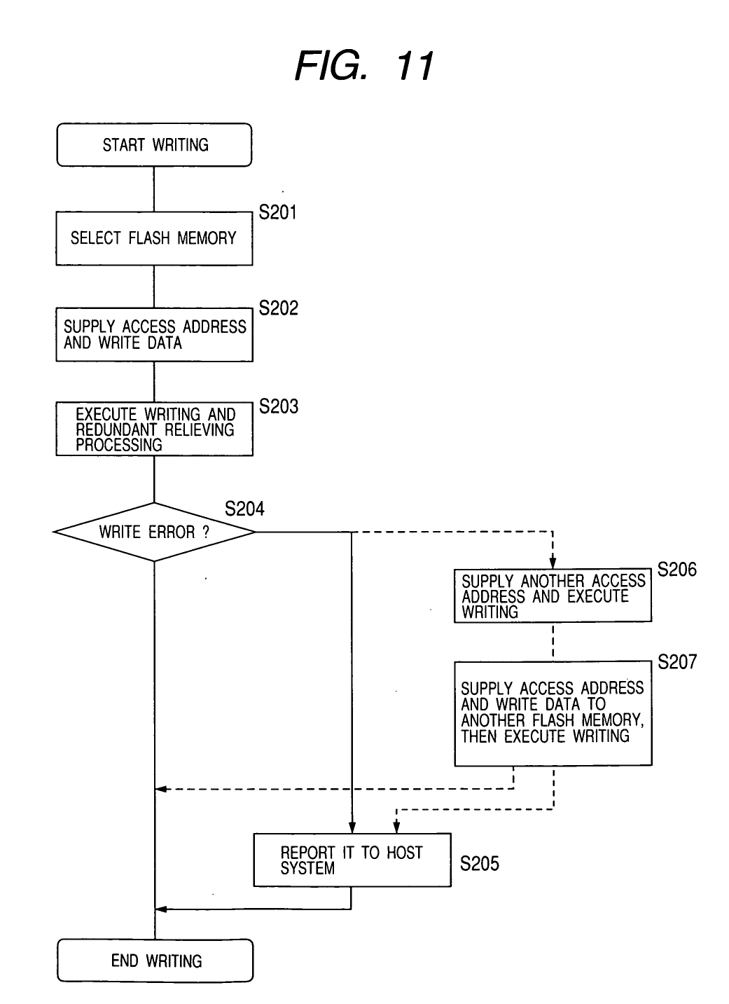

FIG. 10 shows a block diagram of the flash memory of the present invention used as a memory card and FIG. 11 shows an flowchart of the processings by the memory card.

A flash controller F-CNT shown in FIG. 10 selects a flash memory FLASH to be accessed according to an address supplied from an external host system HS (step S201) and supplies a write command, an access address, and write data to the selected flash memory (step S202). In the selected flash memory, the controller executes write processings as shown in FIG. 3. If a write error occurs in the writing, the controller makes a redundant relieving processing. If the maximum value is set in the pointer PTR in step S3, however, the flash memory sets “1” in the abnormal end bit of the status register to notify the flash controller of the end of the write operation (step S203).

The flash controller F-CNT reads the status register of the flash memory to check whether or not “1” is set in the read abnormal end bit in response to the end of the write operation notice received from the flash memory (step S204). If the check result is YES (“1”), the flash controller F-CNT notifies the host system of the write error occurrence and the host system executes an error recovery processing for the write error (step S205). The write error may also be corrected by the flash controller F-CNT, which is provided with an address translation table ATB at that connection, so that when a write error occurs, the controller specifies an access address that is different from the error-occurred one and instructs the flash memory to write the data therein (step S206). Furthermore, the flash controller F-CNT may also select a flash memory different from the error-occurred one and instruct the selected flash memory to write the data therein (step S207).

Because the flash controller controls flash memories in this way, wasteful sectors are reduced from the memory card and the reliability of the memory card is further improved.

As described above, according to the present invention, in the non-volatile semiconductor storage device that enables data to be written/erased therein/therefrom electrically, the time for performing each test before delivery is reduced, thereby the unit price of the chips is reduced. Furthermore, because a redundancy circuit is used for redundant reliving processings even after the delivery of the subject chip, the non-volatile semiconductor storage device can omit address management by a controller. The system price can thus be reduced. Those are the effects to be obtained by the present invention.

While the preferred embodiment of the present invention has been described, it is to be understood that modifications will be apparent to those skilled in the art without departing from the spirit of the invention. For example, while redundant relieving processings are executed only for relieving defective sectors, that is, row addresses in the embodiment, the processings may also be executed for the bit line direction, that is, for column addresses.

And, while a description has been made for a flash memory in which the logic of write data and read data is inverted from each other, the present invention may also apply to another flash memory in which the same logic is assumed for both write data and read data. In that connection, the processing in step S5 in the flowchart shown in FIG. 3 is omitted.

Furthermore, while the content in the status register 15 is output through the input/output terminals I/O0 to I/O7 according to the state of a combination of both chip enable signal and out enable signal selected from among the control signals inputted to the flash memory from external in the embodiment, it may also be output according to a combination of other control signals and it may always be output when the Ready/Busy signal R/B state is Ready (High level). Furthermore, an address is allocated to the status register 15 and the status register may be provided with a decoder, so that the content of the status register 15 is read according to the address inputted from external.

Furthermore, while the FN tunnel phenomenon is used to write/erase data in/from storage elements provided with a floating gate respectively in the above embodiment, the present invention may also apply to another flash memory composed so that writing is done with use of hot electrons generated with a drain current while erasing is done with use of the FN tunnel phenomenon. Furthermore, the present invention may also apply to a multi-level flash memory that stores data consisting of 2 or more bits in one storage element.

While a description has been made mainly for a flash memory, which is an application field of the present invention, the application field of the present invention is not limited only to that. The present invention may also apply a variety of semiconductor memories provided with non-volatile semiconductor storage elements respectively to each of which a voltage is applied so as to change the threshold voltage therein and record information therein.

What is claimed is:

1. A method for producing a non-volatile semiconductor storage device comprising a memory array that includes a plurality of non-volatile storage elements and a plurality of spare storage elements, each of which enables information to be written/erased therein/therefrom electrically, and configured so that each storage element decided to be defective in a normal operation is replaced with one of said spare storage elements and information related to the defective storage element is recorded in a predetermined area provided in said memory array,
wherein information related to the defective storage element is not stored in the predetermined area provided in said memory array even when the defective storage element is detected in a test while said non-volatile semiconductor storage device is extracted as a non-defective product if the number of defective storage elements detected in the test is a predetermined value or lower.

2. The method according to claim 1, wherein said test is divided into two tests; one test is performed for a wafer from which chips are not cut apart yet while the other test is performed for the respective chips cut apart from the wafer as products.

3. A method for producing a non-volatile semiconductor storage device comprising a memory array that includes a plurality of non-volatile storage elements and a plurality of spare storage element, each of which enables information to be written/erased therein/therefrom electrically, and a trimming circuit for adjusting characteristics of an internal circuit, and configured so that adjustment information of said trimming circuit is stored in a predetermined area provided in said memory array according to a result of a test while a storage element decided to be defective in a normal write operation is replaced with one of said spare storage elements and information related to the defective storage element is stored in the predetermined area provided in said memory array,
wherein adjustment information of said trimming circuit detected in the test is stored in the predetermined area provided in said memory array while information related to a defective storage element detected in the test is not stored in the predetermined area provided in said memory array and each non-volatile semiconductor storage device is extracted as a non-defective product if the number of defective storage elements detected in the test is a predetermined value or lower.

4. The method according to claim 3, wherein said test is divided into two tests; one of the tests is performed for a wafer from which chips are not cut apart yet while the other test is performed for the respective chips cut apart from the wafer as products.

5. A method for producing a non-volatile semiconductor storage device comprising a memory array that includes a plurality of non-volatile storage elements and a plurality of spare storage elements, each of which enables information to be written/erased therein/therefrom electrically, and a trimming circuit for adjusting characteristics of an internal circuit, and configured so that information related to each defective storage element of said plurality of non-volatile storage elements and adjustment information of said trimming circuit are stored in a predetermined area provided in said memory array,
wherein adjustment information of said trimming information detected in a test performed for a wafer from which chips are not cut apart yet and information related to a defective storage element detected in the test performed for the respective chips cut apart from said wafer are stored in the predetermined area provided in said memory array, and an aging or burning-in test is performed for respective chips, then another test is performed for them so that the adjustment information of said trimming circuit detected in said test and the information related to each defective storage element detected in said test are stored in the predetermined area provided in said memory array.

6. The method according to claim 5, wherein each chip in which the number of unused spare storage elements except for those that take the places of defective storage elements according to said test performed for the respective chips is a predetermined value or higher is extracted as a non-defective product.

7. A non-volatile semiconductor storage device comprising a memory array that includes a plurality of non-volatile storage elements and a plurality of spare storage elements, each of which enables information to be written/erased therein/therefrom electrically, and configured so that information related to each defective storage element of said plurality of non-volatile storage elements is stored in a predetermined area in said memory array,
wherein said storage device further includes:
a volatile storage circuit for retaining information related to each defective storage element of said plurality of non-volatile storage elements during an operation;
an address comparison circuit for comparing information retained in the storage circuit with inputted address information; and
a selection circuit for selecting one of said spare storage elements according to an output from the address comparison circuit.

8. The storage device according to claim 7;
wherein said storage device further includes a trimming circuit for adjusting characteristics of an internal circuit; and
wherein adjustment information of said trimming circuit is stored in a predetermined non-volatile area in said memory array while the adjustment information of said trimming circuit that is active is stored in said non-volatile storage circuit.

9. The storage device according to claim 7,
wherein said non-volatile storage circuit retains the inputted address information; and
wherein if information cannot be written in any of said plurality of non-volatile storage elements during an operation, the defective storage element is replaced with one of said plurality of spare storage elements, then information is written in said spare storage element while said address information retained in said non-volatile storage circuit is transferred to and stored in the predetermined area in said memory array.

10. The storage device according to claim 9, wherein if said spare non-volatile storage element that takes the place of said defective storage element is defective, said address information retained in said non-volatile storage circuit is invalidated.
